(19) United States
(12) Patent Application Publication
(10) Pub. No.: US 2013/0333923 A1
(43) Pub. Date: Dec. 19, 2013

(54) MODULATED COMPOSITIONAL AND STRESS CONTROLLED MULTILAYER ULTRATHIN CONFORMAL SiNx DIELECTRICS USED IN NANO DEVICE FABRICATION

(71) Applicants: Mihaela Balseanu, Cupertino, CA (US); Stephan A. Cohen, Wappingers Falls, NY (US); Alfred Grill, White Plains, NY (US); Thomas J. Haigh, JR., Claverack, NY (US); Son V. Nguyen, Schenectady, NY (US); Mei-Yee Shek, Palo Alto, CA (US); Hosadurga Shobha, Niskayuna, NY (US); Li-Qun Xia, Cupertino, CA (US)

(72) Inventors: Mihaela Balseanu, Cupertino, CA (US); Stephan A. Cohen, Wappingers Falls, NY (US); Alfred Grill, White Plains, NY (US); Thomas J. Haigh, JR., Claverack, NY (US); Son V. Nguyen, Schenectady, NY (US); Mei-Yee Shek, Palo Alto, CA (US); Hosadurga Shobha, Niskayuna, NY (US); Li-Qun Xia, Cupertino, CA (US)

(73) Assignee: INTERNATIONAL BUSINESS MACHINES CORPORATION, Armonk, NY (US)

(21) Appl. No.: 13/495,545

(22) Filed: Jun. 13, 2012

(51) Int. Cl. C23C 16/34; H05K 1/02

(52) U.S. Cl. CPC C23C 16/345; H05K 1/0298
USPC 174/251; 428/216; 427/535

(57) ABSTRACT

A layer of silicon nitride having a thickness from 0.5 nanometers to 2.4 nanometers is deposited on a substrate. A plasma nitridation process is carried out on the layer. These steps are repeated for a plurality of additional layers of silicon nitride, until a predetermined thickness is attained. Such steps can be used to provide a multilayer silicon nitride dielectric formed on a substrate having an upper surface of dielectric material with Cu and other conductors embedded within, and a plurality of steps. The multilayer silicon nitride dielectric has a plurality of individual layers each having a thickness from 0.5 nanometers to 2.4 nanometers, and the multilayer silicon nitride dielectric conformally covers the steps of the substrate with a conformality of at least seventy percent. A multilayer silicon nitride dielectric, and a multilevel back end of line interconnect wiring structure using same, are also provided.

### STATEMENT OF GOVERNMENT RIGHTS

Not Applicable.

### CROSS-REFERENCE TO RELATED APPLICATIONS

Not Applicable.

### FIELD OF THE INVENTION

The present invention relates to the electrical, electronic and computer arts, and, more particularly, to microelectronic semiconductor fabrication and/or nano-scale device fabrication processes and materials with Cu-Low k dielectric interconnect, and the like.

### BACKGROUND OF THE INVENTION

Plasma-enhanced chemical vapor deposition (PECVD) is a process used to deposit thin films from a gas state (vapor) to a solid state on a substrate. Chemical reactions are involved in the process, which occur after creation of a plasma of the reacting gases. The plasma is generally created by RF (AC) frequency or DC discharge between two electrodes, the space between which is filled with the reacting gases.

Capping layers are employed on the top surface of a low-k dielectric in an interconnect structure to prevent the diffusion of Cu into the dielectric, or be a barrier to oxidation of Cu, thereby providing reliability to the integrated circuit.

### SUMMARY OF THE INVENTION

Principles of the invention provide techniques for modulated compositional and stress controlled multilayer ultrathin conformal SiNx dielectrics used in nano device fabrication. In one aspect, an exemplary method includes the steps of providing a substrate, wherein the substrate has a plurality of steps; depositing on the substrate a layer of silicon nitride having a thickness from 0.5 nanometers to 2.4 nanometers; carrying out a plasma nitridation process on the layer to densify and control stress of the layer; and repeating the steps of depositing and carrying out plasma nitridation for a plurality of additional layers of silicon nitride, until a predetermined thickness is attained, wherein the predetermined thickness of the layers conforms to the steps of the substrate with a conformality of at least seventy percent. In another aspect, an exemplary structure includes a substrate having an upper surface of dielectric material with Cu and/or other conductors embedded within. The surface further has a plurality of steps. The structure also includes a multilayer silicon nitride dielectric formed on the substrate. The multilayer silicon nitride dielectric has a plurality of individual layers each having a thickness from 0.5 nanometers to 2.4 nanometers. The multilayer silicon nitride dielectric conformally covers the steps of the substrate with a conformality of at least seventy percent.

In still another aspect, a multilevel back end of line interconnect wiring structure includes a plurality of interconnect wiring metal layers; and a plurality of insulating dielectrics. The metal layers are embedded in the insulating dielectrics. The insulating dielectrics separate the metal layers. Also included are a plurality of caps separating given ones of the metal layers from a corresponding one of the insulating dielectrics associated with a next higher wiring level. At least one of the caps is a multilayer silicon nitride dielectric cap having a plurality of individual layers each having a thickness from 0.5 nanometers to 2.4 nanometers.

In a further aspect, a multilayer silicon nitride dielectric includes a plurality of individual silicon nitride layers, each of the layers having a thickness from 0.5 nanometers to 2.4 nanometers.

As used herein, “facilitating” an action includes performing the action, making the action easier, helping to carry the action out, or causing the action to be performed. Thus, by way of example and not limitation, instructions executing on one computer processor might facilitate an action carried out by a piece of semiconductor processing equipment, by sending appropriate command(s) to cause or aid the action to be performed. For the avoidance of doubt, where an actor facilitates an action by other than performing the action, the action is nevertheless performed by some entity or combination of entities.

Techniques of the present invention can provide substantial beneficial technical effects. For example, one or more embodiments may provide one or more of the following advantages:
high conformality;
good stress control;
high breakdown voltage;
reduced leakage;
lower dielectric constant, k
multilayer to lengthen diffusion pathway
reduce pinhole
high compressive stress and material stability under UV cure

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 is a cross-sectional view of a structure for which cap capacitance is simulated, in accordance with an aspect of the invention;

FIG. 2 is a graph of metallization layer 2 total capacitance versus cap film thickness, in accordance with an aspect of the invention;

FIG. 3 is a table of various dielectric caps;

FIG. 4 is a graph of capacitance change versus cap thickness, in accordance with an aspect of the invention;

FIG. 5 shows a structure with via chamfering, in accordance with an aspect of the invention;

FIGS. 6 and 7 present scanning electron micrographs of chamfering, in accordance with an aspect of the invention;

FIGS. 8 and 9 present tables of exemplary fabrication steps of the film, in accordance with an aspect of the invention;

FIGS. 10 and 11 present tables of exemplary stress values, in accordance with an aspect of the invention;

FIG. 12 is a scanning transmission electron microscope (STEM) view of a multilayer film, in accordance with an aspect of the invention;

FIG. 13 shows results of deposition in accordance with the prior art;

FIG. 14 shows results of deposition in accordance with an aspect of the invention;

FIG. 15 shows surface flatness and copper-barrier corner integrity, in accordance with an aspect of the invention;

FIG. 16 shows stress change versus barrier thickness, in accordance with an aspect of the invention;

FIG. 17 shows stress change versus treatment power, in accordance with an aspect of the invention;

FIG. 18 presents tabular data for conformal nitride deposited and UV cured in accordance with an aspect of the invention;

FIG. 19 presents dielectric constant (k) data in tabular and bar graph form, in accordance with an aspect of the invention;

FIG. 20 is a graph of percent occurrence versus absolute breakdown field, in accordance with an aspect of the invention;

FIG. 21 is a graph of current density versus field, in accordance with an aspect of the invention;

FIG. 22 presents tabular data for a copper oxidation barrier study, in accordance with an aspect of the invention;

FIGS. 23-26 are photomicrographs of Cu surface oxidation samples, in accordance with an aspect of the invention;

FIG. 27 presents tabular data for a conformal ultrathin SiNₓ, in accordance with an aspect of the invention;

FIG. 28 is a graph of percent occurrence versus absolute breakdown field, in accordance with an aspect of the invention;

FIG. 29 is a graph of current density versus field, in accordance with an aspect of the invention;

FIG. 30 presents tabular data for a thermal voltage stress study, in accordance with an aspect of the invention;

FIGS. 31-33 are graphs of capacitance versus voltage of Triangular-Voltage Sweep tests;

FIG. 34 presents thin silicon nitride compositional tabular data, in accordance with an aspect of the invention;

FIGS. 35 and 36 are graphs of atomic concentration versus sputter time, in accordance with an aspect of the invention; and

FIG. 37 illustrates a standard definition of conformality, as known from the prior art.

### DETAILED DESCRIPTION OF PREFERRED EMBODIMENTS

One or more embodiments advantageously provide a very thin (≦30 nm) robust Cu barrier diffusion barrier conformal cap suitable for meeting the device performance requirements of the interconnects for next generations 14/10/7 nm technology nodes. Unlike current PECVD SiN caps, one or more embodiments provide sufficient step coverage for Cu recess structures to produce a reliable ultrathin cap. One or more embodiments provide a new conformal compositional modulated, stress controlled, and highly conformal ultrathin SiN cap and the associated film's formation process, with various applications in nano device fabrication and the like.

One or more embodiments provide conformal compositional modulated and stress controlled multilayer ultrathin SiNx dielectrics and corresponding film formation processes, suitable, for example, for nano device fabrication in both front end of line (FEOL) and back end of the line (BEOL) applications, such as stressor (stress controlled film), liner, and Cu cap. For example, at least some embodiments provide ultrathin multilayer conformal (≧70%) SiNₓ dielectrics with excellent stress control, using modulated radio frequency (RF) plasma nitridation treatment.

In at least some cases, inventive SiN films have excellent step coverage over recess structures (e.g., nano Cu recess structures) including multilayer conformal structures. In at least some instances, inventive films have excellent stress control from compressive to tensile.

One or more embodiments provide ultrathin SiNₓ dielectrics useful in applications such as low temperature dielectrics stressor in FEOL, Cu cap in BEOL, spacer and liner for nano devices fabrication, and the like. For example, at least some instances provide excellent gap fill of the Cu damascene recess structure in sub-50 nm Cu-ULK (Ultra low-k=ULK), with enhanced reliability and reduction in the required cap thickness. Furthermore, at least some embodiments provide improved stress stability to UV exposure, an oxidation barrier for ultrathin caps, and/or minimal or no damage in the ULK/cap interface due to initial low RF plasma deposition power.

In one or more embodiments, the inventive film is provided in the form of multilayers with thickness ≦25 nm for Cu applications.

One or more embodiments provide an ultrathin conformal nitride film formation process, including using low RF plasma power to deposit nano thick (0.5-3 nm thick) highly conformal SiN by a PECVD, PE-ALD, or CVD (PE-ALD=Plasma Enhanced Atomic Layer Deposition; CVD=chemical vapor deposition) process at low temperatures (<450 C); using a plasma nitridation process with nitrogen bearing reactant gas (example: N₂/NH₃ . . . with inert gas); and repeating the aforementioned two steps to achieve the desirable film thickness.

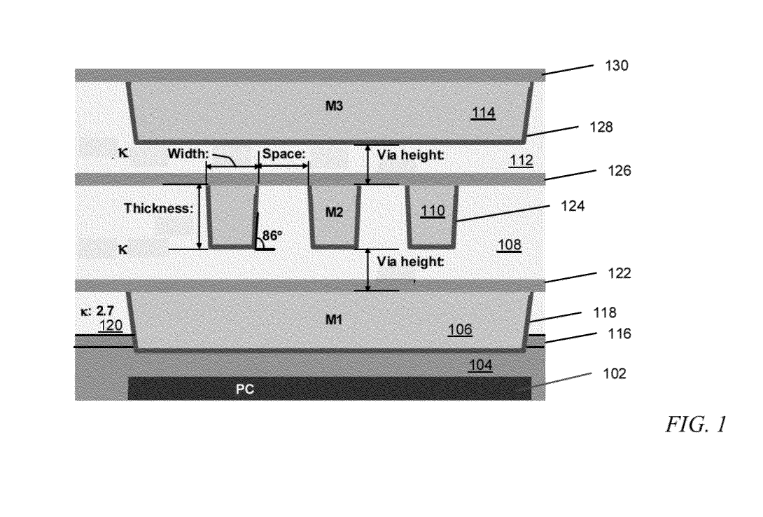

FIG. 1 is a cross-sectional view of a structure for which cap capacitance is simulated, in accordance with an aspect of the invention; in particular, cap capacitance is simulated for 22 nm and 14 nm technology nodes. At present, 25 nm is the lower thickness limit for reliable SiCNH cap (etch stop layer, k ˜5.3). The structure includes a contact layer 102, a substrate 104, and a first metal layer 106. A layer of SiCOH dielectric with k=2.7 is provided at 120. A second layer of porous SiCOH dielectric with an optionally lower k value is provided at 108. A third layer of porous SiCOH dielectric with an optionally lower k value is provided at 112. Note that first metal layer 106, second metal layer 110 and third metal layer 114 are copper. Note that the dielectric silicon oxide or SiCOH layer 116; dielectric caps layer 122; layer 126; and layer 130 are dielectric cap material and that the change from SiCNH to ultrathin multilayer SiN is significant in one or more embodiments of the invention. Note also Ta/TaN liner layer 118 on the bottom and sides of metal layer 106; Ta/TaN layer 124 on the bottom and sides of metal layer 110; Dielectric Cap layer 126; and Ta/TaN layer 128 on the bottom and sides of metal layer 114. In each case, the via height is about 60 nm. The pitch and width of the metal structures in layer 110 are each 40 nm, the thickness is 85 nm, and the included angle is 86 degrees.

It is worth noting that the capacitance is undesirable and it is desired to reduce the capacitance. It is also worth noting that the geometry is complex and the capacitance is not predicted by the simple parallel plate formula.

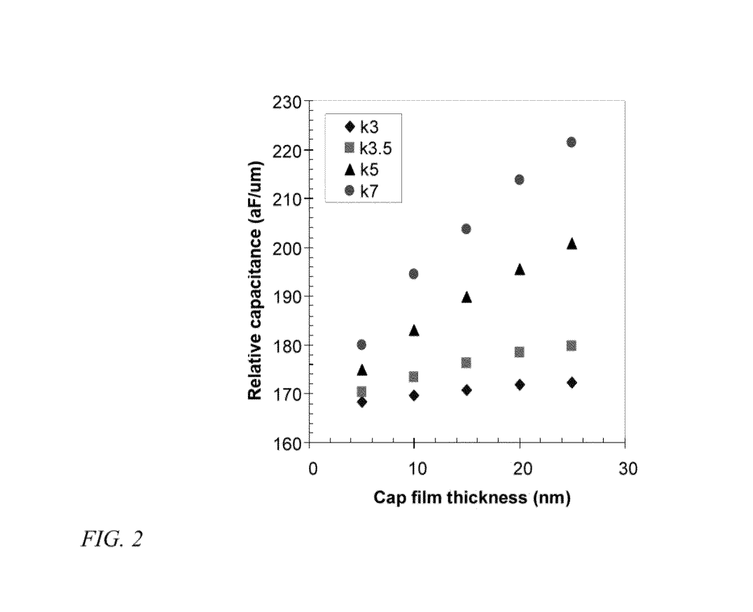

FIG. 2 is a graph of metal layer 2 total capacitance versus cap film thickness. The diamonds are for k3, the squares for k3.5, the triangles for k5, and the circles for k7. The model was for pre-T0 14 nm M2 with pSiCOH 2.4 ILD (Via height Fix). It is seen that M2 capacitance reduces with decrease in cap thickness and k value.

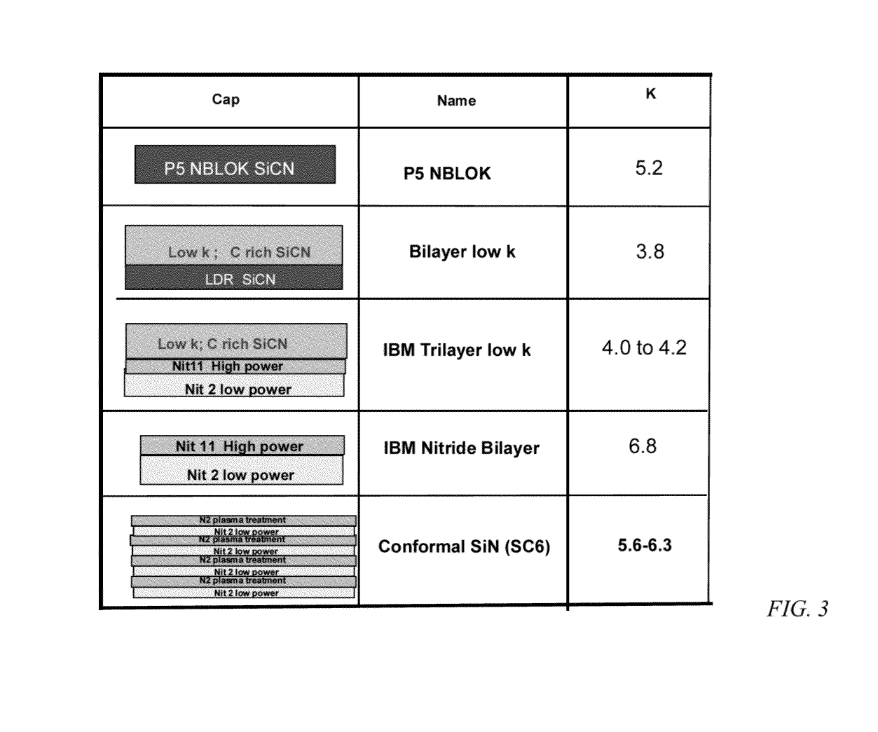

FIG. 3 is a table of various dielectric caps and their K values. The last row is for an embodiment of the invention.

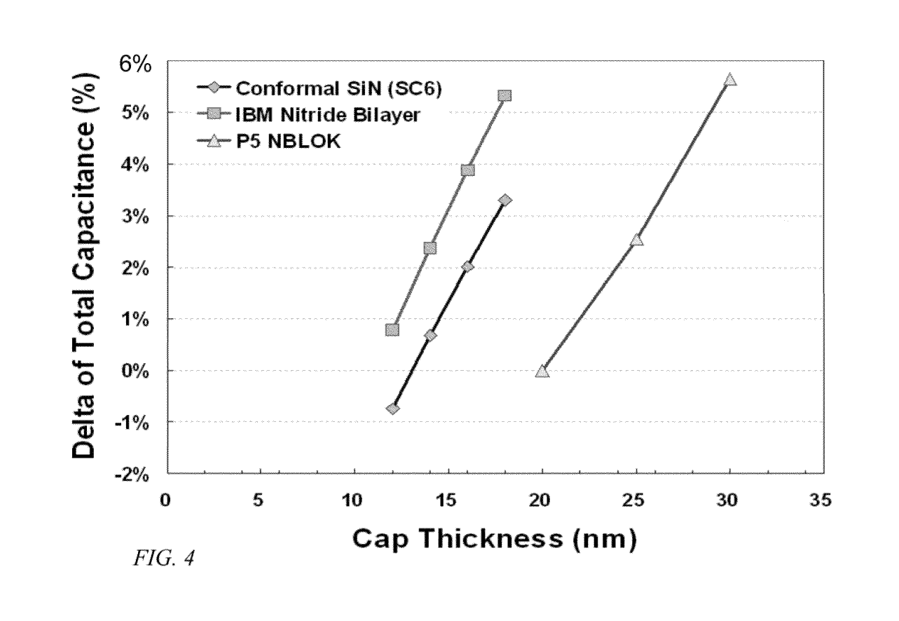

FIG. 4 is a graph of capacitance change versus cap thickness. In particular, note the capacitance change from baseline Process on Record (POR) (20 nm SiCNH, SiCOH 2.7) for k=6.8 (IBM Nitride—square symbols), 6.3 (conformal SiN—diamond symbols), 5.3 (SiCNH—triangle symbols). Both of the Conformal SiN and SiCNH were tested in 14 nm 1^{st} metallization level in BEOL device structure.

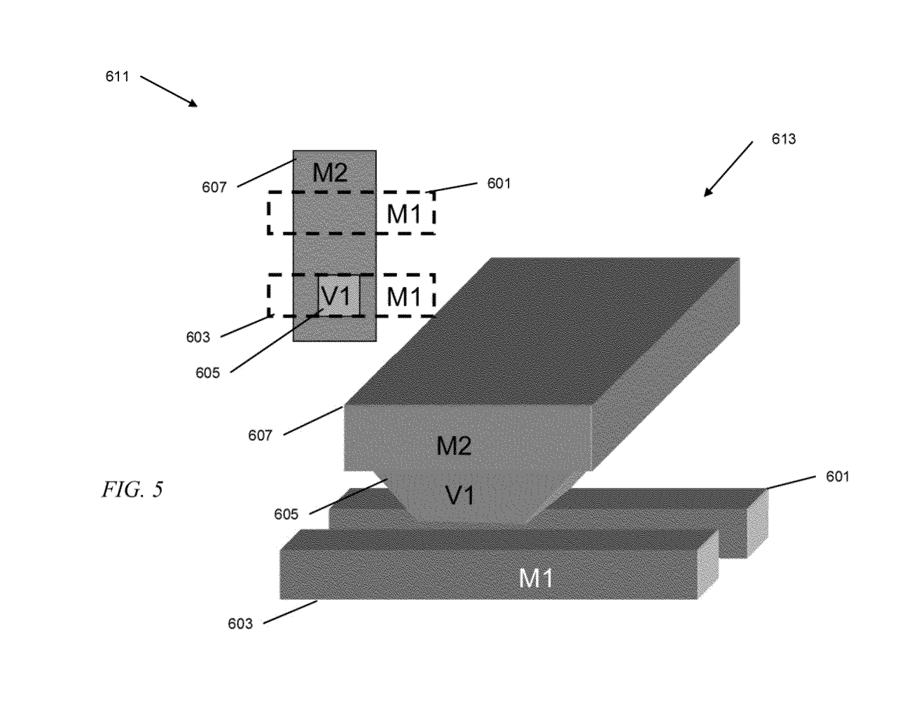

FIG. 5 shows a structure with via chamfering, in accordance with an aspect of the invention. Note pictorial view 613 and top view 611. Note also first metal layer 601, 603; via 605; and second metal layer 607. Note via chamfer (bottom) to adjacent line spacing/control/min insulator is an issue in some cases—28 nm BEOL device is seeing challenges from vias in wideline situations (>50 nm wide). This creates a Time-dependent dielectric breakdown (TDDB) risk for the via to underlying adjacent metal. In 20 nm BEOL device, the process window will be smaller due to scaling.

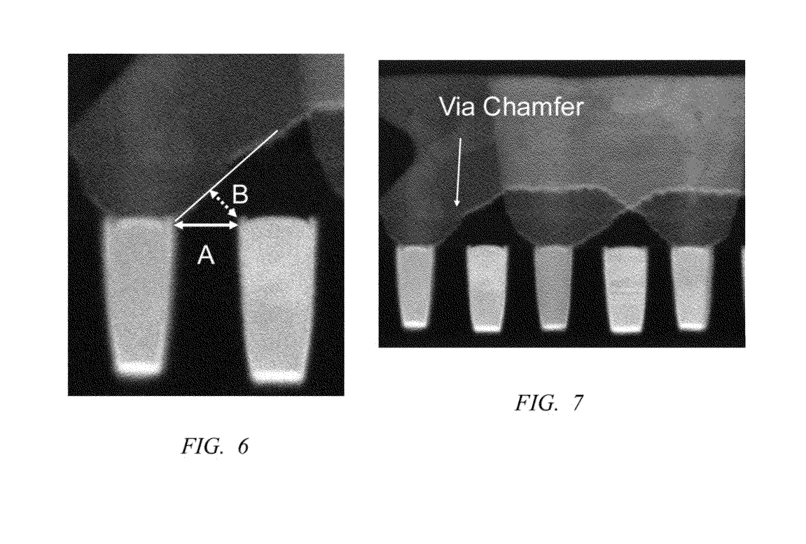

FIGS. 6 and 7 present scanning electron micrographs of chamfering, in accordance with an aspect of the invention. FIG. 6 is an enlarged view of the via chamfer in FIG. 7. Consider a nm BEOL device case with the via (Vx) in wideline, Mₓ as a metal layer, and Mₓ₊₁ as a next highest metal layer. FIGS. 6 and 7 shows initial Vx level chamfer results for 64 nm pitch for metal M2/Via 1 of a 20 nm BEOL. Previous technologies (22/32 nm devices) ground rule calculations/Vmax/Min insulator focused on horizontal distance (“A”) between Vx and Mx metal line below. The Vx chamfer to adjacent different net Mx min insulator space is now “B,” not “A” as shown in FIGS. 6 and. 7. For 14 nm device with 56/45 nm pitch, ground rules calculator/min insulator evaluated with “B,” and chamfer angle=45 degrees and 90 degrees; “A,” no chamfer. With 56 pitch, more ground rules are broken when chamfer=45 degrees (“B”) as compared to assuming no chamfer (“A”). Therefore, the focus in one or more embodiments is increasing the robustness of the dielectric by improving it to achieve high breakdown voltage and reduced leakage.

One or more embodiments provide an ultrathin multilayer conformal (≧70%) SiNₓ dielectrics with excellent stress control with modulated RF plasma nitridation treatment. One or more instances of inventive SiN films have excellent step coverage over recess structures (nano Cu recess structure) including multilayer conformal structures. One or more embodiments of inventive films have excellent stress control from compressive to tensile.

One or more embodiments provide ultrathin SiNₓ dielectrics for use in applications such as low temperature dielectrics stressor in FEOL, Cu cap in BEOL, spacer(s) and liner(s) for nano devices fabrication, and the like. One or more embodiments provide excellent gap fill of the Cu damascene recess structure in sub-50 nm Cu-ULK; this advantageously provides enhanced reliability and reduces the required cap thickness. Furthermore, one or more embodiments provide improved stress stability to UV exposure, oxidation barrier for ultrathin cap, high breakdown voltage (for minimum dielectric chamfer applications); and/or minimal or no damage in the ULK/cap interface due to initial low RF plasma deposition power.

One or more embodiments of an inventive film include multilayers with thickness ≦25 nm for Cu cap applications.

One or more embodiments provide an ultrathin conformal nitride film formation process. Low RF plasma power is used to deposit nanometer thick (0.5-3 nm thick) highly conformal SiN by one of PECVD, PE-ALD, CVD process at low (<450 C) temperature. A plasma nitridation process is carried out with nitrogen bearing reactant gas (example: N₂/NH₃ . . . with inert gas). The previous two steps are repeated to achieve the desirable film thickness. The composition of each ultrathin layer can easily be slightly modified by changing deposition conditions and/or deposition time.

It is worth noting that PECVD multilayer films deposited by SiH₄+NH₃ are known but are not conformal (<50% conformality). Furthermore, plasma nitridation by N₂ of thin films is known but it has not heretofore been used to change the film's stress. One or more embodiments advantageously provide the combination of low RF plasma power to produce ALD-like ultrathin (1-3 nm) films to enhance conformality, followed by N₂ plasma nitridation to densify the film by low energy plasma ion bombardment, and Si—N bonds formation the film, and to change it to a desirable stress, and increase breakdown voltage, reduce leakage, and/or slightly lower k using the multilayer process steps set forth herein.

It is worth noting that conventional multilayer PECVD SiN films do not have high conformality and it is difficult to deposit ultra-thin (5-10 nm) conformal films using such technologies due to the high deposition rate.

One or more embodiments of the inventive film have excellent stress control from compressive to tensile.

One or more instances provide ultrathin SiNₓ dielectrics for applications such as low temperature dielectrics stressor in FEOL, Cu Cap in BEOL, spacer and liner for nano devices fabrication, and the like.

One or more embodiments provide excellent gap fill of the Cu damascene recess structure in sub-50 nm Cu-ULK interconnect, especially filling Cu recess metal line/structures, thus providing enhanced reliability and reducing the required cap thickness. One or more embodiments provide improved stress stability to UV exposure, an oxidation barrier for ultrathin cap(s), high breakdown voltage that will help address the minimum dielectric chamfer issue, and/or minimal or no damage in the ULK/cap interface due to initial low RF plasma deposition power.

In one or more instances, inventive films include multiple layers with thickness ≦25 nm for Cu applications.

One or more embodiments provide an ultrathin conformal nitride film formation process that is not possible with conventional PECVD process. In this aspect, low RF plasma power is used to deposit nano thick (0.5-3 nm thick) highly conformal SiN by using a PECVD/PE-ALD/CVD process at low (<420 C) temperature. A plasma nitridation process is used with nitrogen-bearing reactant gas (example: N₂, NH₃ . . . with inert gas). The aforementioned two process steps are repeated to achieve a desirable film thickness.

It is worth noting that prior-art conformal ALD or CVD SiN will not have stress controlled (varying) feature and normally requires high Processing (>420 C) temperature to achieve good film properties (e.g., high breakdown and the like).

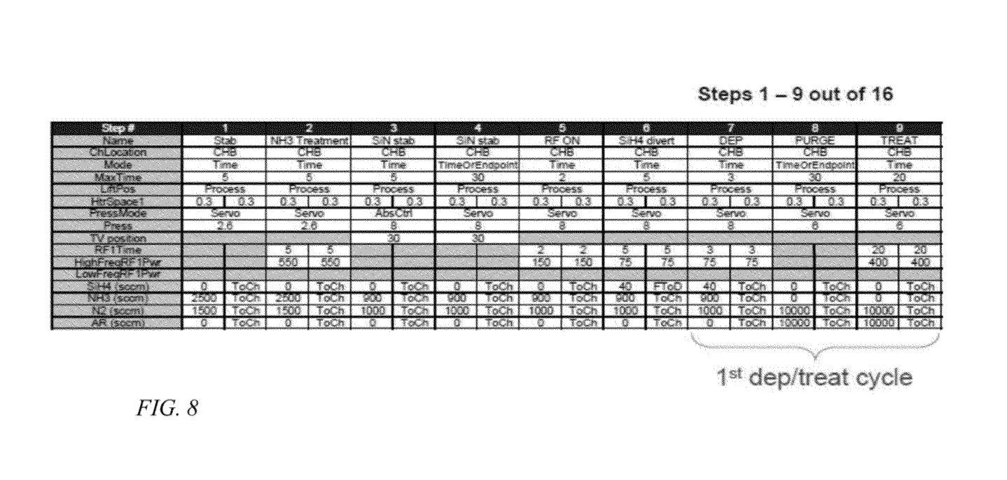

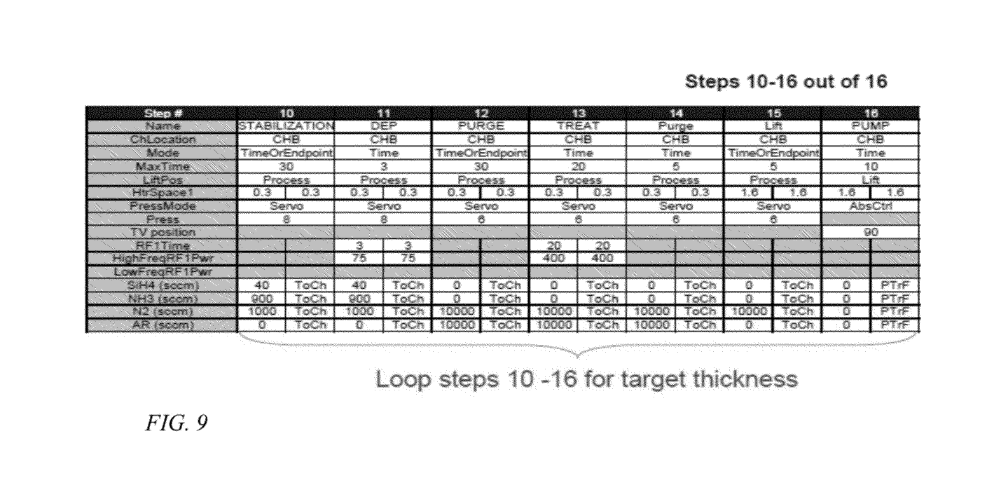

FIGS. 8 and 9 present tables of exemplary fabrication steps. In one or more embodiments, conformal Nitride Recipes include cycling low RF of SiNx deposition (SiNx) and Plasma Nitridation. Each cycle deposits about 19A SiH4/NH₃ using PECVD, and with N₂/Ar used as a nitridation reactant. In some instances, the first deposition-treatment cycle is not set-up outside the loop, to allow for diverting SiH₄ for deposition on the Cu. In one or more embodiments, adjust the number of loops to achieve the desirable target thickness, taking into account the first loop thickness.

In step 1, evacuate the vessel. In step 2, optionally carry out ammonia treatment, introducing ammonia and nitrogen. Pressure is expressed in Ton; the reactant flows are expressed in standard cubic centimeters per minute (SCCM). The power is expressed in Watts and the time in seconds. The reactor was a commercially available 300 mm PECVD tool Applied Materials Producer (Applied Materials, Inc., Santa Clara, Calif., USA). It will be appreciated that some parameters, such as electrode spacing/wafer position and reactor volume, are tool-specific and will vary in different tools and/or applications. In steps 3 and 4, stabilize at 8 Torr. In step 5, turn on the power; in step 6, lower the power and add SiH₄ as a reactant. In step 7, carry out deposition; in step 8, purge; and in step 9, treat using N₂ and Argon. Steps 7-9 thus comprise a first deposition and treatment cycle. In step 10, carry out stabilization. In step 11, carry out deposition. In step 12, purge. In step 13, carry out treatment. In step 14, purge. In step 15, lift. In step 16, pump. Steps 10-16 are repeated until the desired thickness is obtained, taking into account the initial deposition in steps 7-9. In one or more embodiments, each loop deposits about 19 Angstroms/2 nm. In one or more embodiments, varying the NH₃ flow varies the composition.

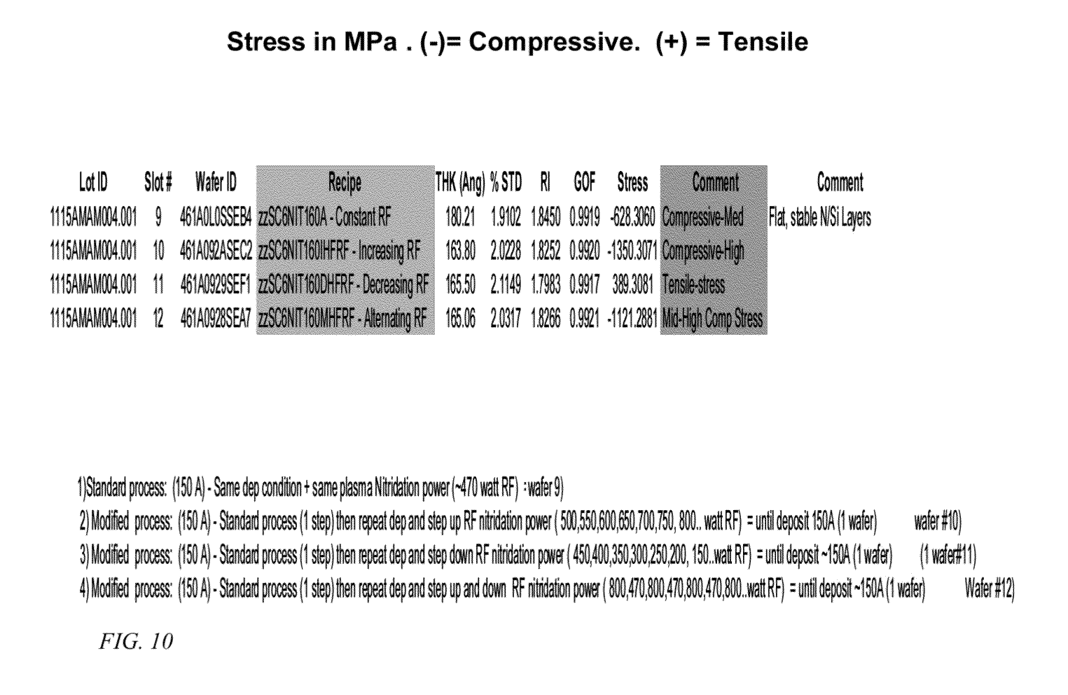

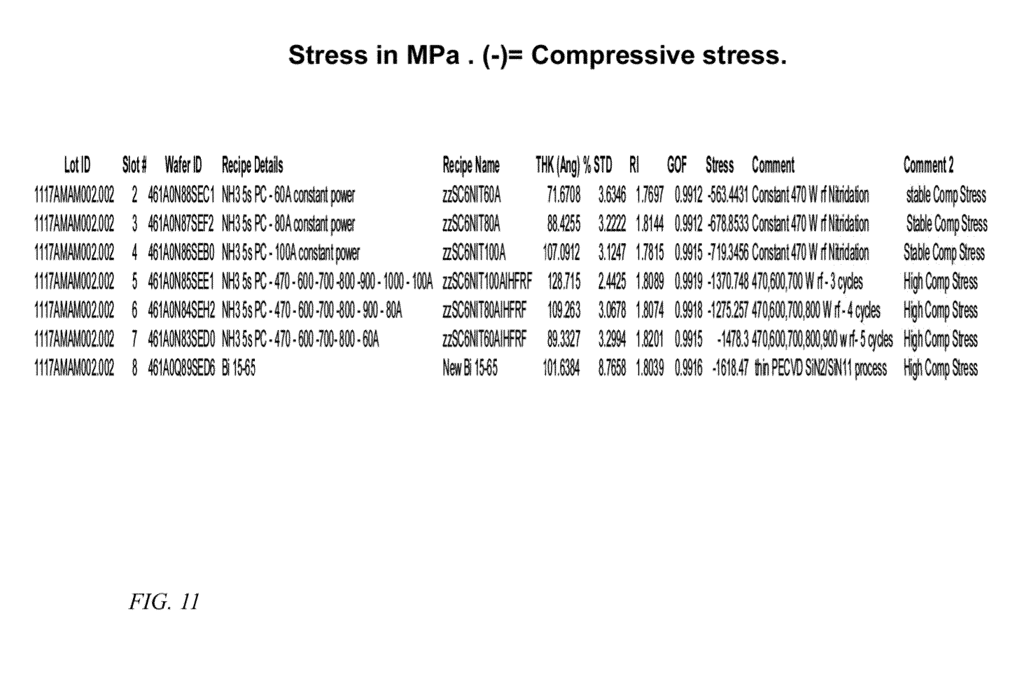

FIGS. 10 and 11 present tables of exemplary stress values. Note that Lot IDs, slot numbers, and wafer IDs are not necessarily independently significant, but are useful to identify the different samples. FIG. 10 demonstrates that ultrathin conformal SiN, provides excellent stress control from compressive to tensile with RF plasma surface treatment for each layer. It can be seen that there is minimal change in the average film bulk composition for SiN. The stress values are in MPa. A minus sign indicates compressive stress while a plus sign indicates tensile stress. FIG. 11 demonstrates that ultra-thin 70-120 A conformal SiN, provides excellent compressive stress Control for Cu Cap applications. Again, stress is in MPa and a minus sign indicates compressive stress.

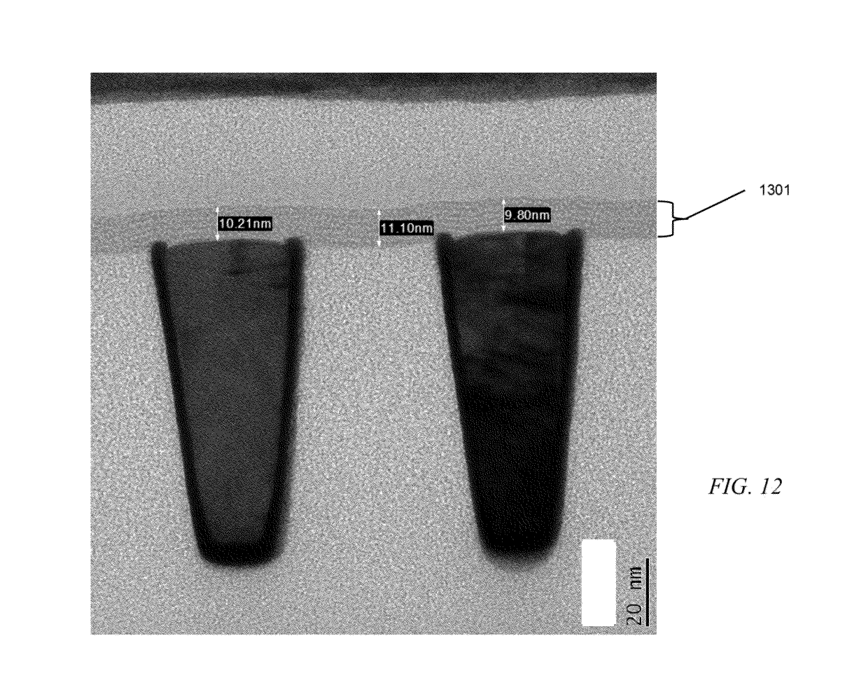

FIG. 12 is a scanning transmission electron microscope (STEM) view of a conformal Nitride multilayer film 1301 (100 Angstroms) in accordance with an embodiment of the invention. Note the good Cu recess coverage and the visibility of the multi layer film's structure.

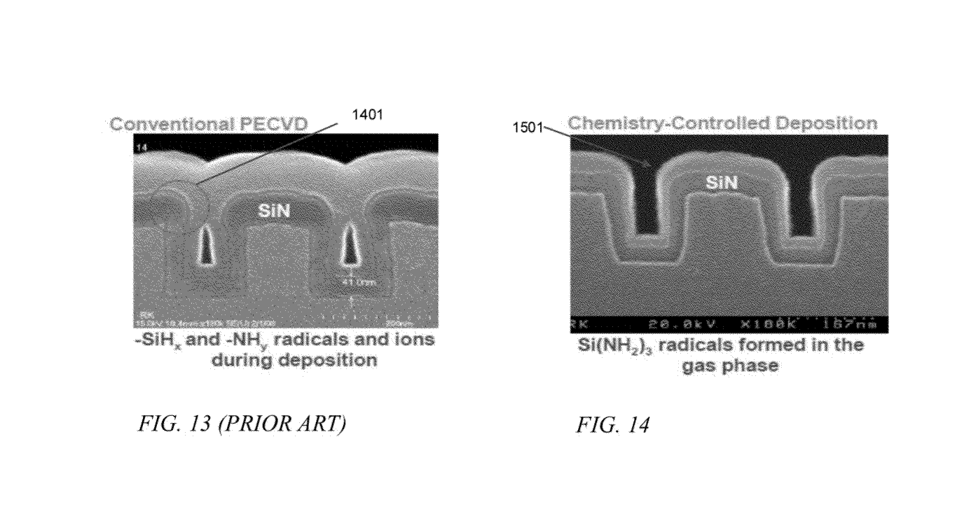

FIG. 13 shows results of deposition in accordance with the prior art, while FIG. 14 shows results of deposition in accordance with an aspect of the invention. Note that in one or more embodiments, conformal SiN in accordance with an aspect of the invention provides improved conformality (to ˜70%). Note the bread loafing 1401 in the prior art view of FIG. 13, using conventional PECVD, wherein SiHₓ and NH_{y} radicals are formed during deposition. Compare to the good conformality 1501 in FIG. 14, using chemistry-controlled deposition, wherein Si(NH₂)₃ radicals are formed in the gas phase. In one or more embodiments, a conformal nitride layer is formed via a new deposition concept based on Low RF power to form conformal radical for the deposition. Initial deposition is used to achieve the best step coverage, with follow-up plasma treatment to tune the film properties such as stress and density. The deposition/treatment cycle is repeated to achieve the desired film thickness. The treatment step is used to reduce the Si—H content and slightly increase Si—N surface's bonding density from the initial SiN deposition, improving the dielectric properties to the desired values.

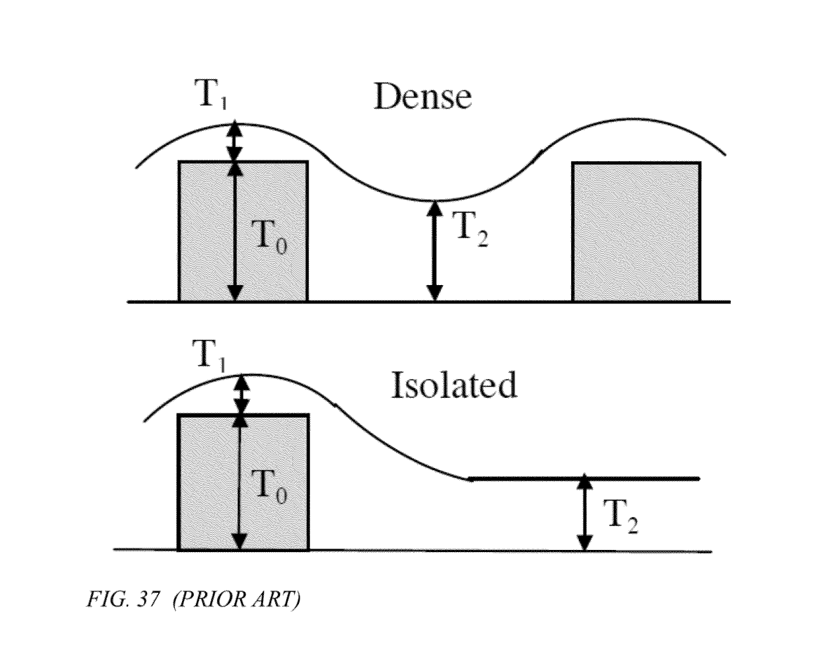

It is worth noting that the commonly used definition of conformality in the semiconductor industry is as shown below, and used herein, where T₁ is the maximum film thickness on the top of the step, T₂ is the minimum film thickness at the bottom of the trench (or remote from the step, in the case of an isolated feature), and Tₒ is the step height. See FIG. 37.

Conformality=1−(T₂−T_{I})/T₀×100%

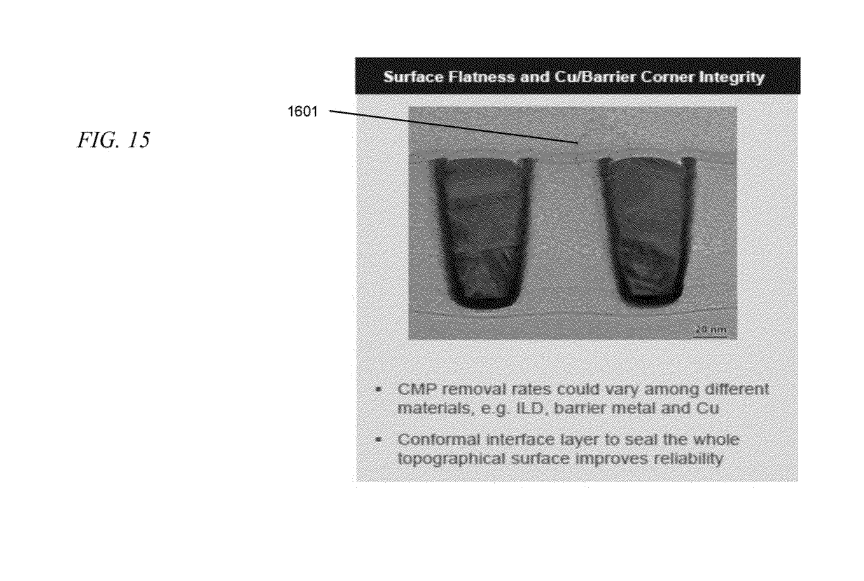

FIG. 15 shows surface flatness and copper-barrier corner integrity 1601, in accordance with an aspect of the invention. Use of one or more embodiments as a Cu cap is believed appropriate due to better Cu recess fill as compared to prior art techniques. For development of a thin barrier, it will be appreciated that next-generation barrier requirements include SiCN or SiN barriers with thicknesses less than 100 Angstroms. Conformality is important for corner integrity. A Cu diffusion barrier is often appropriate, as is hermiticity. It is appropriate to evaluate conformal SiN films, determine the minimum SiN thickness for Cu diffusion barrier and hermiticity, and seek Cu diffusion and/or hermiticity improvement. It is worth noting that CMP removal rates could vary among different materials; for example, uneven topographical porous SiCOH dielectric is normally removed faster than barrier metal, and Cu under. A conformal interface layer is also advantageous to seal the whole topographical surface, improve planarity and improve reliability.

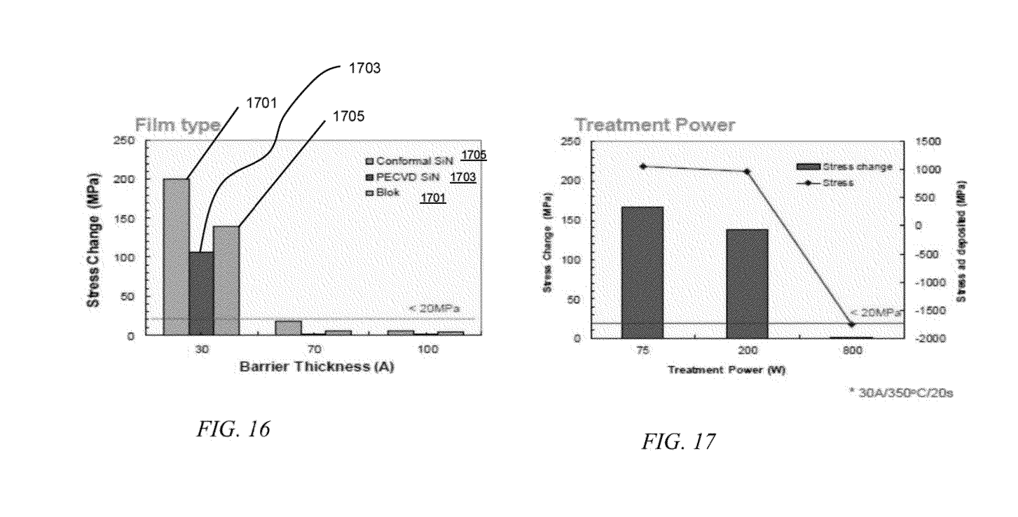

FIG. 16 shows stress change versus barrier thickness, in accordance with an aspect of the invention; and FIG. 17 shows stress change versus treatment power, in accordance with an aspect of the invention. Note the improved moisture resistance of the conformal SiN liner with film property tuning and hermeticity. Conformal Nitride shows a better hermeticity control window than convention PECVD processes. In FIG. 16, left bar 1701 is for SiCNH; middle bar 1703 is for PECVD SiN, and right bar 1705 is for Conformal SiN.

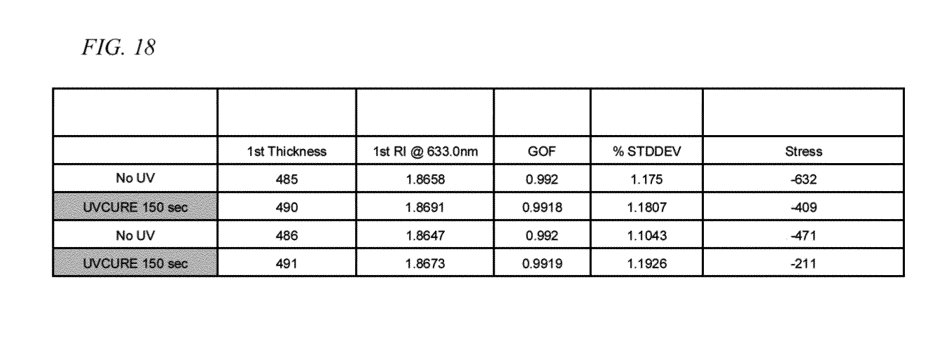

FIG. 18 presents tabular data for conformal Nitride deposited in accordance with an aspect of the invention; in particular, conformal Nitride deposited in a commercial 300 mm system as mentioned above. Note that stress remains compressive post-UV for SiN film deposited with SiH4/NH3 and stable RF plasma treatment power at 470 W.

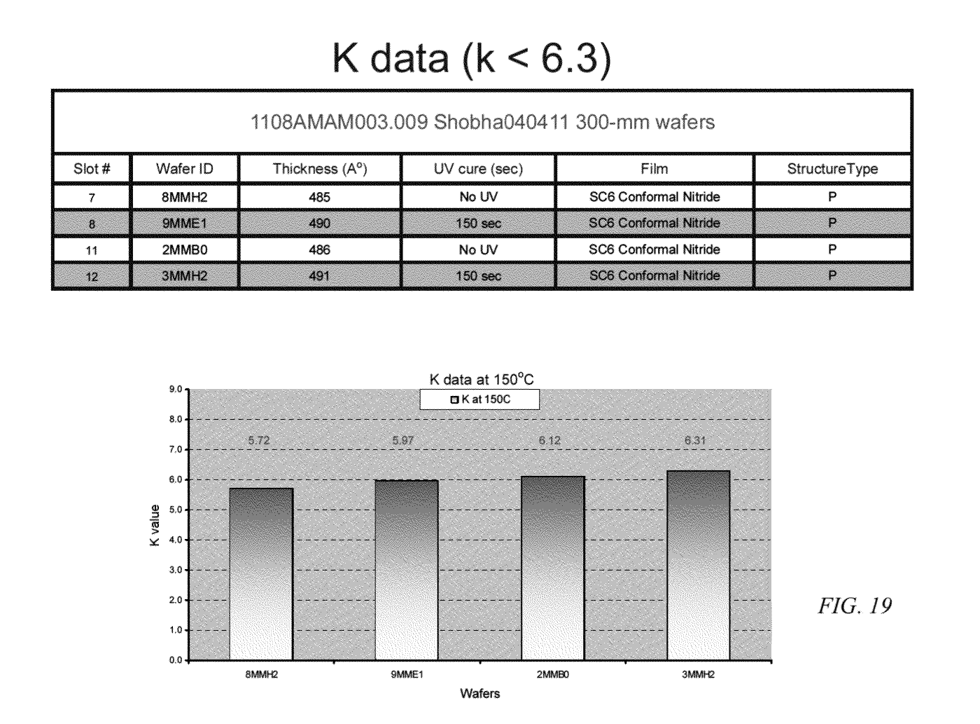

FIG. 19 presents dielectric constant data in tabular and bar graph form, in accordance with an aspect of the invention.

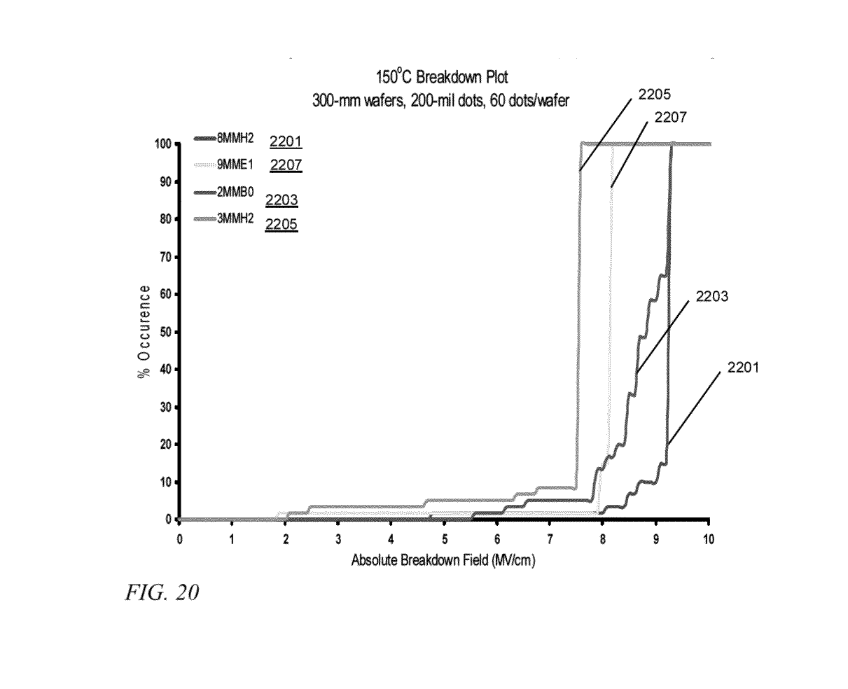

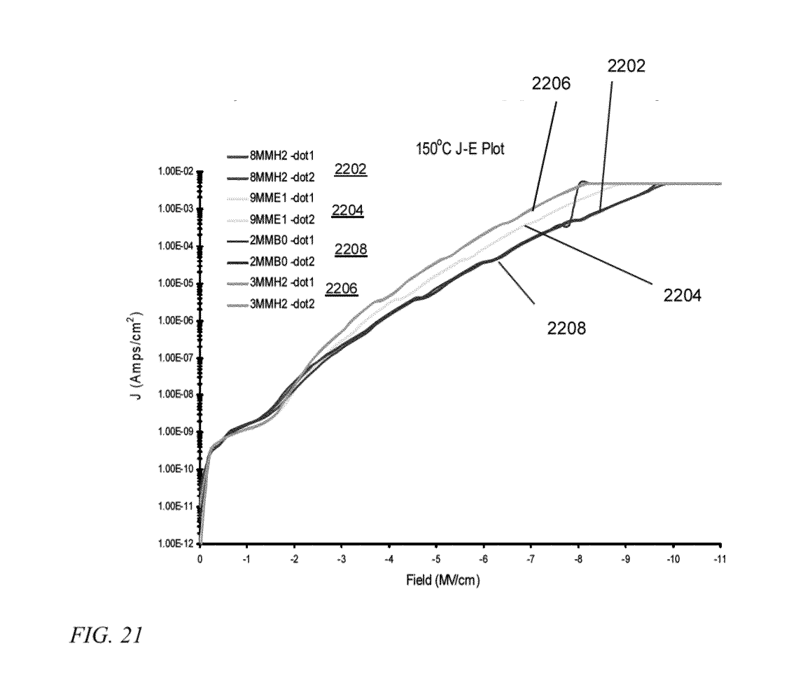

Note that conformal SiN, has high breakdown (>7 Mv/cm) and low leakage (<1E-7 at 2 MV/cm applied field). FIG. 20 is a graph of percent occurrence versus absolute breakdown field, in accordance with an aspect of the invention; and FIG. 21 is a graph of current density versus field, in accordance with an aspect of the invention. In FIG. 20, curve 2201 is for wafer sample 8MMH2; curve 2207 is for wafer sample 9MME1; curve 2203 is for wafer sample 2MMB0; and curve 2205 is for wafer sample 3MMH2. In FIG. 21, curve 2202 is for wafer sample 8MMH2; curve 2208 is for wafer sample 9MME1; curve 2204 is for wafer sample 2MMB0; and curve 2206 is for wafer sample 3MMH2. The dot 1 and dot 2 notation in the sample labels refer to the center and edge location. It should be note that curve 2202 and curve 2208 are nearly identical and laying on top of each other.

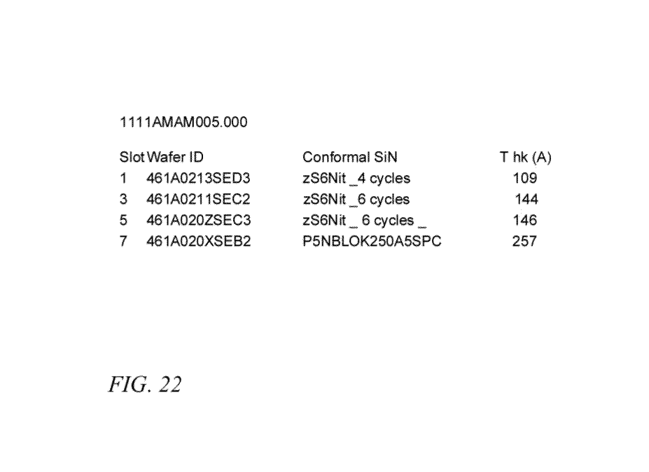

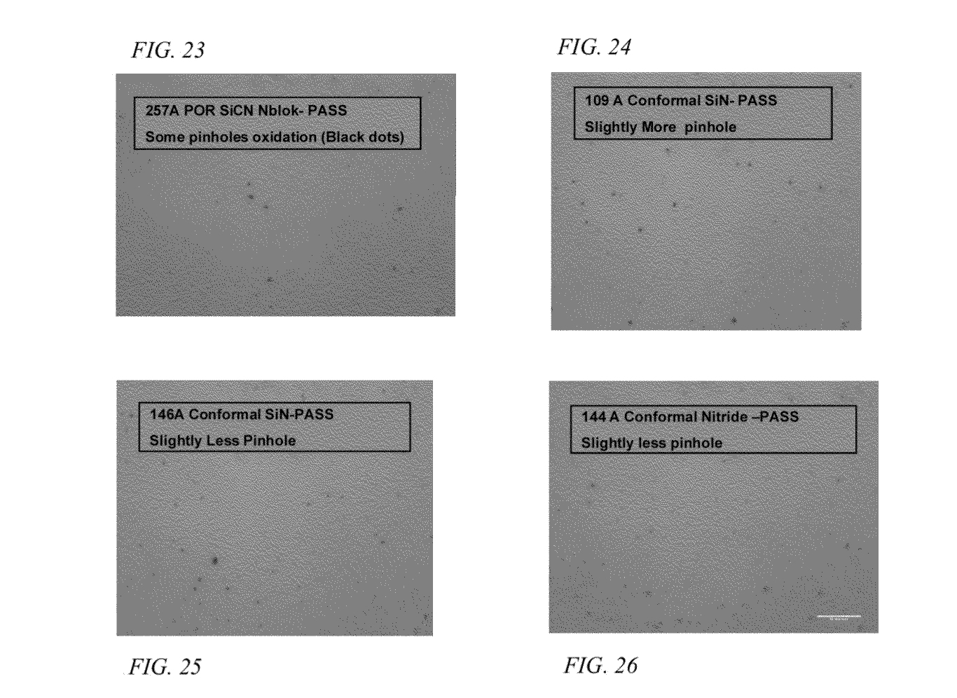

FIG. 22 presents tabular data for a copper oxidation barrier study, in accordance with an aspect of the invention. The thickness (Thk) is expressed in Angstroms (A). In particular, the study was for 100-145 A conformal Nitride and 250 A POR SiCNH (310 C in air ambient, 24 hr.). All samples passed and all samples have 5 sec NH₃ plasma pre-clean (processed in Applied Material Producer tool). SiN film was deposited on Cu substrate. Thickness is measured by F5 ellipsometry on SiN on Si substrate. TEM physical thickness is normally about 10-20% thinner. FIGS. 23-26 are photomicrographs of samples corresponding to the data of FIG. 22 that passed oxidation barrier test of air exposure at 310 C for 24 hr.

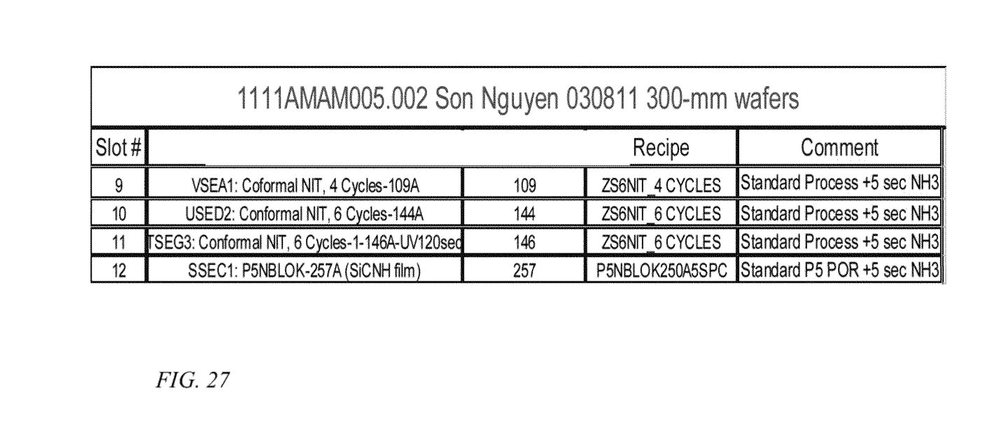

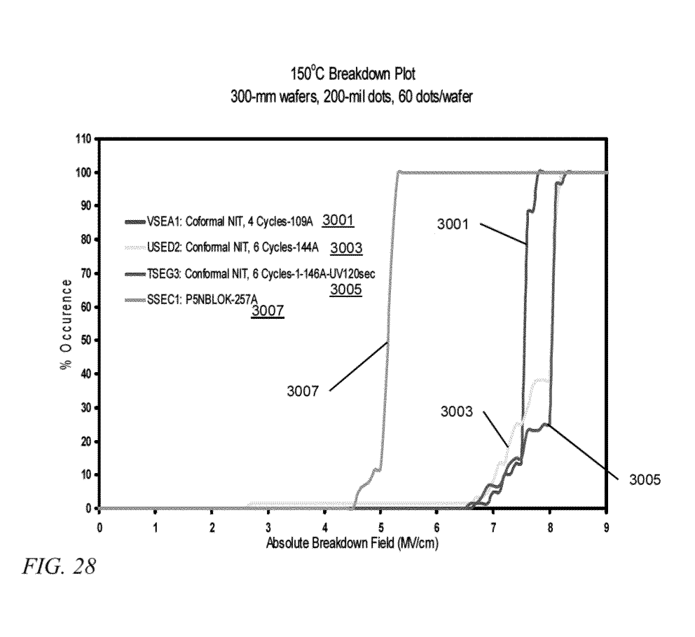

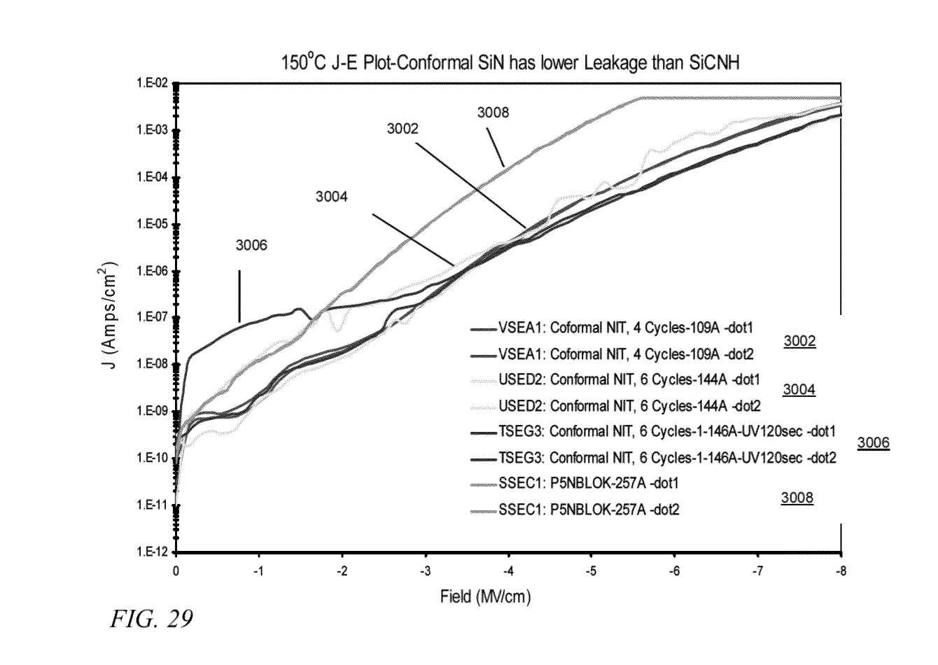

FIG. 27 presents tabular data for conformal ultrathin SiNₓ, in accordance with an aspect of the invention. In particular, it is seen that conformal ultrathin (100-140 A) SiNₓ has high breakdown (>7 vs. 4-5 MV/cm) and low leakage (<1 E-7 at 2 MV/cm applied field) as compared to 250 A POR SiCNH. FIG. 28 is a graph of percent occurrence versus absolute breakdown field for the data of FIG. 27, in accordance with an aspect of the invention; and FIG. 29 is a graph of current density versus field for the data of FIG. 27, in accordance with an aspect of the invention. In FIG. 28, curve 3001 is for the first row of data of the table of FIG. 27; curve 3003 is for the second row of data of the table of FIG. 27; curve 3005 is for the third row of data of the table of FIG. 27; and curve 3007 is for the fourth row of data of the table of FIG. 27. In FIG. 29, curve 3002 is for the first row of data of the table of FIG. 27; curve 3004 is for the second row of data of the table of FIG. 27; curve 3006 is for the third row of data of the table of FIG. 27; and curve 3008 is for the fourth row of data of the table of FIG. 27. The dot 1 and dot 2 notation in the sample labels in FIG. 29 are for the center and edge location. It should be noted that curves 3002, 3004 and 3006 are lower at higher field (>2 MV/cm).

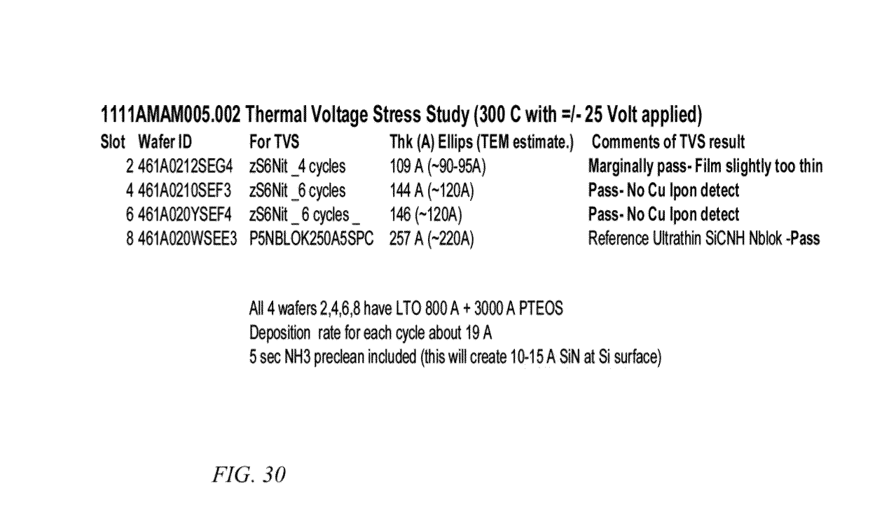

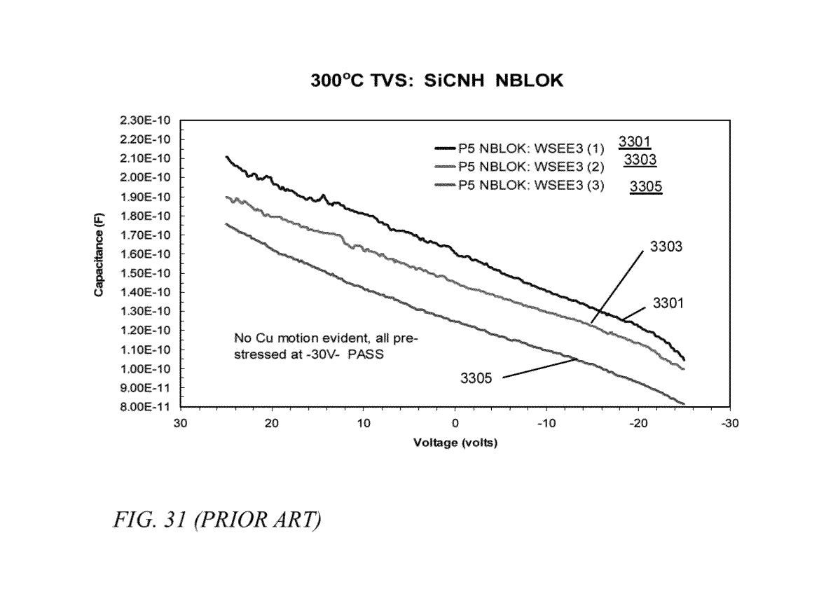

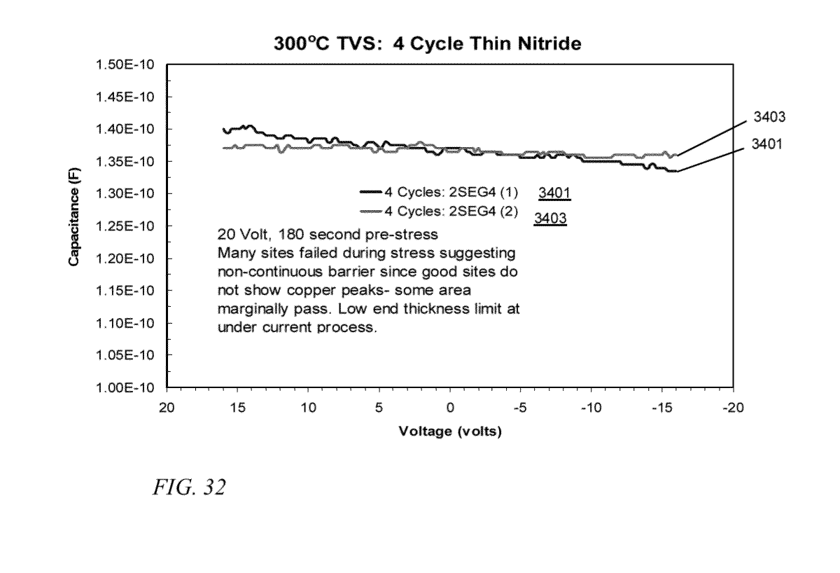

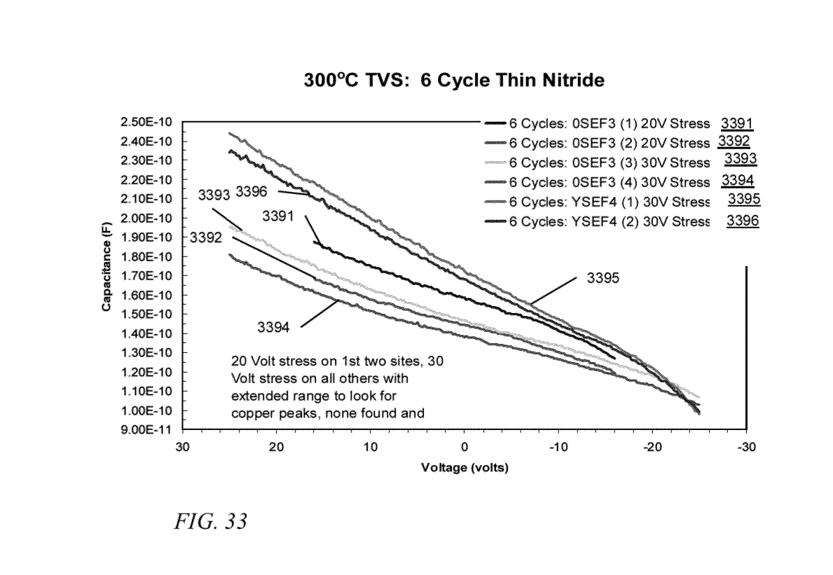

FIG. 30 presents tabular data for a thermal voltage stress study, in accordance with an aspect of the invention; in particular, thermal voltage stress of 100-145 A (90-220 A TEM thickness) conformal SiN and 25 nm POR SiCNH (ellipsometry thickness). FIGS. 31-33 are graphs of capacitance versus voltage for the data of FIG. 30; FIG. 31 being for a prior-art SiCNH approach. FIG. 31 shows the Voltage vs. Capacitance for 220 A SiCNH and the samples passed Cu diffusion test. FIG. 32 shows the Voltage vs. Capacitance for 90-95 A Conformal SiN and the samples marginally passed Cu diffusion test. FIG. 33 shows the Voltage vs. Capacitance for two 120 A Conformal SiN and BOTH samples passed Cu diffusion test.

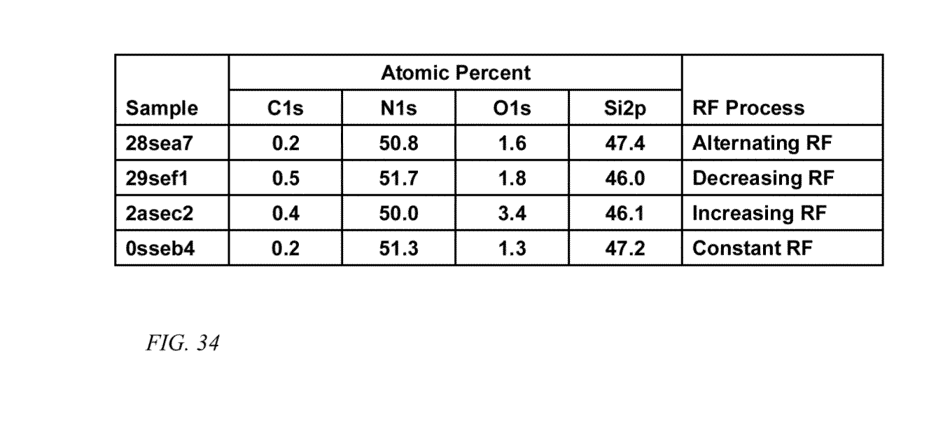

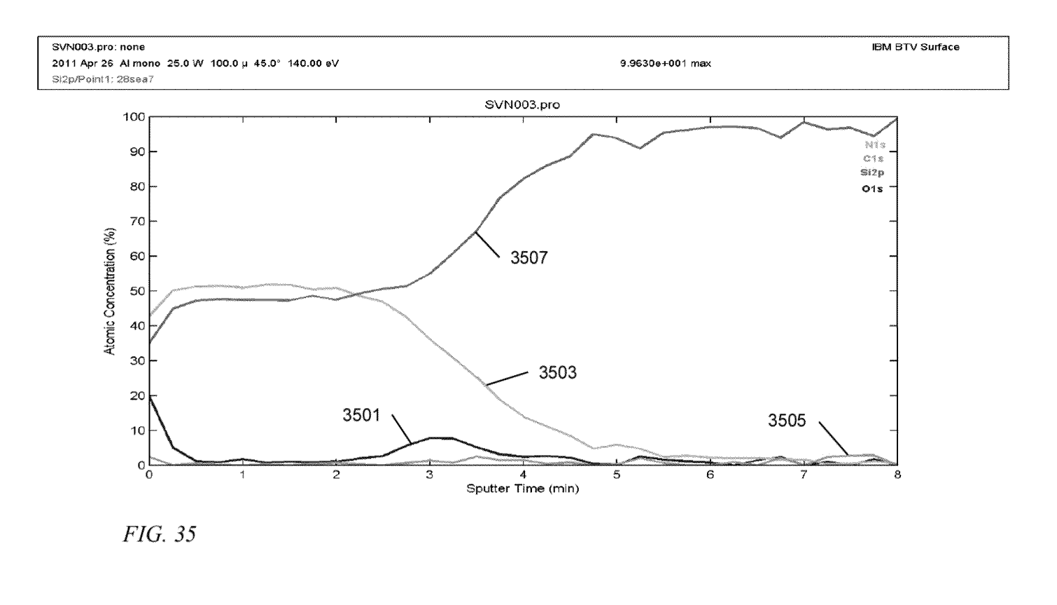

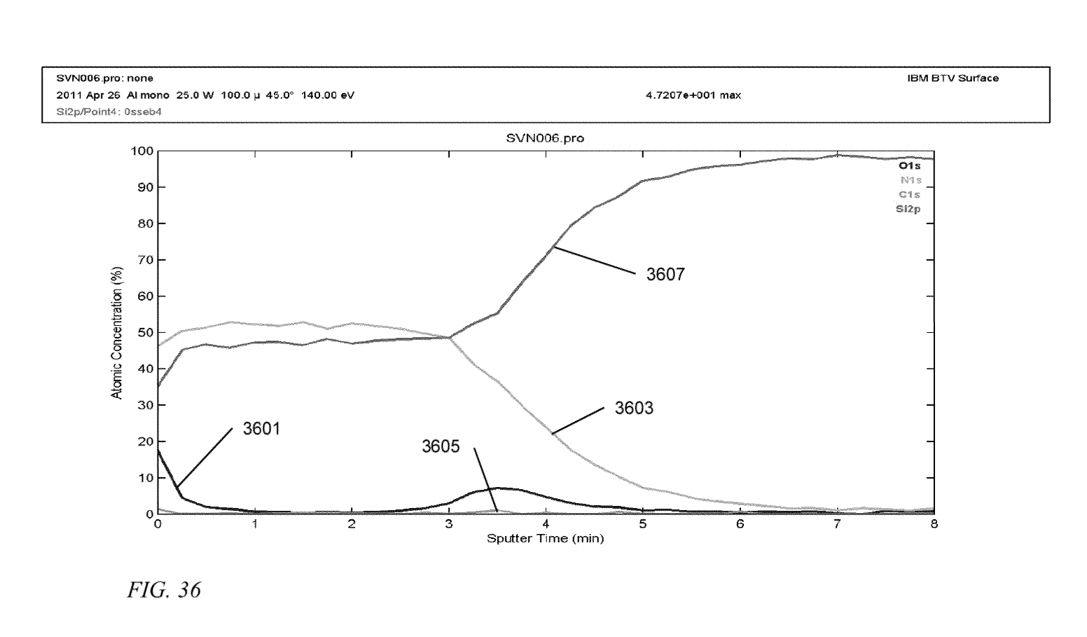

FIG. 34 presents thin silicon nitride tabular data, in accordance with an aspect of the invention, with the deposition conditions as in FIG. 10. Note that XPS depth profiles show no significant change in overall bulk composition. FIG. 35 is a typical graph of atomic concentration versus sputter time for the data of FIG. 34. FIG. 35 is for the first row of data in the table of FIG. 34. The curves 3501, 3503, 3505, and 3507 are, respectively, for O1s, N1s, C1s, and Si2p. In FIG. 36, for the last row of data in FIG. 34, the curves 3601, 3603, 3605, and 3607 are, respectively, for O1s, N1s, C1s, and Si2p.

With regard to the XPS depth profiles, it is worth noting that the compositional differences between the samples is subtle, and very little/small variation is observed on varying the mode of the RF Plasma nitridation power applied during the deposition. In one or more embodiments, sensitive HFS (Hydrogen Forward Scattering)/Rutherford backscattering spectrometry (RBS) is appropriate to detect the differences.

Given the discussion thus far, it will be appreciated that, in general terms, an exemplary method, according to an aspect of the invention, includes the step of providing a substrate. The substrate has a plurality of steps. See FIGS. 14 and 37, e.g. Another step includes depositing on the substrate a layer of silicon nitride having a thickness from 0.5 nanometers to 3 nanometers. See, e.g. step 7 in FIG. 9. A further step includes carrying out a plasma nitridation process on the layer to densify and control stress of the layer. See, e.g., step 9 in FIG. 8. A still further step includes repeating the steps of depositing and carrying out plasma nitridation for a plurality of additional layers of silicon nitride, until a predetermined thickness is attained. See, e.g., steps 11 and 13 in FIG. 9, and the exemplary multilayer structure of 1301 FIG. 12. The predetermined thickness of the layers conforms to the steps of the substrate with a conformality of at least seventy percent. See FIGS. 14 and 37, e.g.

In some cases, the depositing includes plasma enhanced chemical vapor deposition.

In some instances, the depositing is carried out at a temperature of less than 450 degrees Centigrade.

In one or more embodiments, the depositing is carried out at a radio frequency power of less than 2 watts per square centimeter, with a radio frequency ranging from 400 KHz to 60 MHz. Preferably, the depositing is carried out at a radio frequency power of less than 0.3 watts per square centimeter. Preferably, the depositing is carried out with a radio frequency of 13.56 MHz.

The plasma nitridation process can be carried out, for example, with a nitrogen-bearing reactant gas or a mixture of nitrogen-bearing gas with an inert gas.

In one or more embodiments, the plasma nitridation process is carried out to cause a change in the stress of the layers.

In some cases, in the repeating step, the predetermined thickness is no greater than 25 nanometers.

It is worth noting that in one or more embodiments, the plasma nitridation process is carried out to reduce Si—H content of the layers and to improve dielectric properties of the layers with increased Si—N bonding formation and increased film density by nitrogen plasma reactive species reaction and ion bombardment. Furthermore, in some cases, the plasma nitridation process is carried out to adjust leakage (e.g., increase or reduce leakage) and to increase breakdown strength of ultrathin deposited SiN film. Yet further, in some instances, the plasma nitridation process is carried out to increase UV cure stability of ultrathin deposited SiN film and maintain the compressive stress under UV radiation. Still further, in one or more embodiments, the plasma nitridation process is carried out to increase or reduce leakage and to increase breakdown strength of ultrathin deposited SiN film.

It is also worth noting that in some cases, the plasma nitridation process is carried out to increase oxidation resistance and Cu diffusion barrier properties by strengthening each individual layer's interfaces with increased Si—N bonding and density with ion bombardment; and/or the plasma nitridation process is carried out and different increase, decrease, or constant power density is provided in each layer to change the ultrathin nitride film's stress to a desirable level of tensile, compressive or nearly neutral as desired.

In another aspect, an exemplary structure includes a substrate having an upper surface of dielectric material with Cu and/or other conductors embedded within (typically, both copper and non-copper conductors are present; however, for example, in some cases, only copper conductors might be present). See. e.g., FIG. 1. The surface further has a plurality of steps. See, e.g., FIG. 37. Also included is a multilayer silicon nitride dielectric (see, e.g., element 1301 in FIG. 12) formed on the substrate. The multilayer silicon nitride dielectric has a plurality of individual layers each having a thickness from 0.5 nanometers to 2.4 nanometers. The multilayer silicon nitride dielectric conformally covers the steps of the substrate with a conformality of at least seventy percent. See. e.g., FIG. 14.

In some cases, the multilayer silicon nitride dielectric is no greater than 25 nanometers thick.

In some instances, the steps comprise nanoscale copper recess structures.

The skilled artisan will appreciate from the context whether method steps or physical steps as shown in FIG. 37 are being referred to.

In still another aspect, a multilevel BEOL interconnect wiring structure includes metal (interconnect wiring metal layers—conductors (e.g., 106, 110, 114)) separated by insulating dielectrics. See, for example the dielectrics 108, 112, 120 in FIG. 1, and dielectric caps 116, 122, 126, 130 in FIG. 1. Conductors (e.g., 106, 110, 114) are embedded in the intra-level dielectrics. One, some, or all of the caps 116, 122, 126, 130 are multilayer silicon nitride dielectrics separating the conductors embedded in the intra-level dielectrics from the dielectric of the next wiring level. For example, cap 122 separates M1 106 from insulator 108. The multilayer silicon nitride dielectric has a plurality of individual layers each having a thickness from 0.5 nanometers to 2.4 nanometers.

In some instances, the dielectrics and conductors (metal layers) have steps as shown in FIG. 12 or 37 and the multilayer silicon nitride dielectric conformally covers the steps in the dielectrics and conductors with a conformality of at least seventy percent.

In some cases, the multilayer silicon nitride dielectric has a dielectric constant in the range of from 5.6 to 6.3.

In some embodiments, the multilayer silicon nitride dielectric is no greater than 25 nanometers thick.

In a further aspect, a silicon nitride dielectric (130 or 126, 122, 116 in FIG. 1), includes plurality of individual silicon nitride layers. Each of the layers has a thickness from 0.5 nanometers to 2.4 nanometers. The 0.5 nanometer to 2.4 nanometer range can optionally be used in the other embodiments described herein as well. In one or more embodiments, the plurality of individual layers have a total thickness that is no greater than 25 nanometers. In some instances, the multilayer silicon nitride dielectric has a dielectric constant in the range of from 5.6 to 6.3.

The method(s) as described above is/are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
providing a substrate, wherein said substrate has a plurality of steps;
depositing on said substrate a layer of silicon nitride having a thickness from 0.5 nanometers to 2.4 nanometers;
carrying out a plasma nitridation process on said layer to densify and control stress of said layer; and
repeating said steps of depositing and carrying out plasma nitridation for a plurality of additional layers of silicon nitride, until a predetermined thickness is attained;
wherein said predetermined thickness of said layers conforms to said steps of said substrate with a conformality of at least seventy percent.

2. The method of claim 1, wherein said depositing comprises plasma enhanced chemical vapor deposition.

3. The method of claim 1 wherein said depositing is carried out at a temperature of less than 450 degrees Centigrade.

4. The method of claim 1, wherein said depositing is carried out at a radio frequency power of less than 2 watts per square centimeter, with a radio frequency ranging from 400 KHz to 60 MHz.

5. The method of claim 4, wherein said depositing is carried out at a radio frequency power of less than 0.3 watts per square centimeter.

6. The method of claim 5, wherein said depositing is carried out, with a radio frequency of 13.56 MHz.

7. The method of claim 1, wherein said plasma nitridation process is carried out with one of a nitrogen-bearing reactant gas and a mixture of nitrogen-bearing gas with an inert gas.

8. The method of claim 7, wherein said plasma nitridation process is carried out to cause a change in the stress of said predetermined thickness of said layers.

9. The method of claim 1, wherein, in said repeating step, said predetermined thickness is no greater than 25 nanometers.

10. A structure comprising:
a substrate having an upper surface of dielectric material with copper conductors embedded within, said surface further having a plurality of steps; and
a multilayer silicon nitride dielectric formed on said substrate, said multilayer silicon nitride dielectric having a plurality of individual layers each having a thickness from 0.5 nanometers to 3 nanometers, said multilayer silicon nitride dielectric conformally covering said steps of said substrate with a conformality of at least seventy percent.

11. The structure of claim 10, further comprising non-copper conductors embedded in said dielectric material.

12. The structure of claim 11, wherein said multilayer silicon nitride dielectric is no greater than 25 nanometers thick.

13. The structure of claim 11, wherein said steps comprise nanoscale copper recess structures.

14. The structure of claim 11, wherein said multilayer silicon nitride dielectric has a dielectric constant in the range of from 5.6 to 6.3.

15. A multilevel back end of line interconnect wiring structure comprising:
a plurality of interconnect wiring metal layers;
a plurality of insulating dielectrics, said metal layers being embedded in said insulating dielectrics, said insulating dielectrics separating said metal layers; and
a plurality of caps separating given ones of said metal layers from a corresponding one of said insulating dielectrics associated with a next higher wiring level, at least one of said caps comprising a multilayer silicon nitride dielectric cap, said multilayer silicon nitride dielectric having a plurality of individual layers each having a thickness from 0.5 nanometers to 2.4 nanometers.

16. The multilevel back end of line interconnect wiring structure of claim 15, wherein said dielectrics and metal layers have steps and wherein said multilayer silicon nitride dielectric conformally covers said steps in said dielectrics and metal layers with a conformality of at least seventy percent.

17. The multilevel back end of line interconnect wiring structure of claim 15, wherein said multilayer silicon nitride dielectric has a dielectric constant in the range of from 5.6 to 6.3.

18. The multilevel back end of line interconnect wiring structure of claim 15, wherein said multilayer silicon nitride dielectric is no greater than 25 nanometers thick.

19. A multilayer silicon nitride dielectric comprising a plurality of individual silicon nitride layers, each of said layers having a thickness from 0.5 nanometers to 2.4 nanometers.

20. The multilayer silicon nitride dielectric of claim 19, wherein said plurality of individual layers have a total thickness that is no greater than 25 nanometers.

21. The multilayer silicon nitride dielectric of claim 19, wherein said multilayer silicon nitride dielectric has a dielectric constant in the range of from 5.6 to 6.3.
